(19) United States
(12) Patent Application Publication
(10) Pub. No.: US 2023/0309247 A1
(43) Pub. Date: Sep. 28, 2023

(54) DISPLAY DEVICE AND MANUFACTURING METHOD THEREOF

(71) Applicant: Samsung Display Co., LTD., Yongin-si (KR)

(72) Inventors: Hyeji JANG, Asan-si (KR); Myoung An MIN, Cheonan-si (KR)

(21) Appl. No.: 18/100,132

(22) Filed: Jan. 23, 2023

(30) Foreign Application Priority Data
Mar. 22, 2022 (KR) 10-2022-0035480

(51) Int. Cl. H05K 5/02

(52) U.S. Cl. CPC H05K 5/02

(57) ABSTRACT

A display device according to an embodiment includes: a display panel including a first region and a bendable second region connected to the first region; a supporting member supporting the display panel and defining a plurality of opening regions therein overlapping the second region; and a connecting member disposed between the display panel and the supporting member and including a first portion overlapping the plurality of opening regions of the supporting member and a second portion overlapping a region of the supporting member except for the plurality of opening regions, where the first portion of the connecting member has no adhesive property or has a lower adhesive property than the second portion.

This application claims priority to Korean Patent Application No. 10-2022-0035480 filed on Mar. 22, 2022, and all the benefits accruing therefrom under 35 U.S.C. § 119, the content of which in its entirety is herein incorporated by reference.

### BACKGROUND

### (a) Field of the Invention

The present disclosure relates to a display device and a manufacturing method thereof.

### (b) Description of the Related Art

A display device includes a liquid crystal display (“LCD”), a plasma display device (“PDP”), an organic light emitting diode (“OLED”) device, a field emission display (“FED”), and an electrophoretic display device.

A foldable display device that may be folded or unfolded, a rollable display device that may be wound, and a slidable display device that may expand or reduce a display area have been developed.

As such, a support member for supporting a display panel of the display device may have a plurality of opening regions corresponding to curved portions of the display area so that the display area may be easily curved.

### SUMMARY

Embodiments are to provide a display device capable of preventing foreign particles from being injected through a plurality of opening regions of a supporting member supporting a display panel, and a manufacturing method thereof.

However, tasks to be solved by embodiments of the present invention may not be limited to the above-described task, and may be extended in various ways within a range of technical scopes included in the present invention.

A display device according to an embodiment includes: a display panel including a first region and a bendable second region connected to the first region; a supporting member supporting the display panel and defining a plurality of opening regions therein overlapping the second region; and a connecting member disposed between the display panel and the supporting member and including a first portion overlapping the plurality of opening regions of the supporting member and a second portion overlapping a region of the supporting member except for the plurality of opening regions, where the first portion of the connecting member has no adhesive property or has a lower adhesive property than the second portion.

The first portion of the connecting member may include a polymer, and the second portion of the connecting member may include a photo initiator, an oligomer, and a monomer.

The first portion of the connecting member may be photopolymerized by ultraviolet rays to become a polymer.

The second region of the display panel may be a rollable or slidable region.

The supporting member may block light.

The display device may further include an additional supporting layer overlapping the second region and disposed under the supporting member.

The additional supporting layer may overlap a non-opening region of the supporting member disposed between the plurality of opening regions of the supporting member.

The additional supporting layer may not overlap the plurality of opening regions of the supporting member.

The additional supporting layer may block light.

A manufacturing method of a display device according to an embodiment includes: forming a display panel including a first region and a second region that is connected to the first region and is bendable; disposing a connecting member under the display panel; attaching a supporting member supporting the display panel, disposed under the connecting member, and defining a plurality of opening regions therein overlapping the second region; and removing or reducing an adhesive property of a first portion, overlapping the plurality of opening regions of the supporting member, of the connecting member to form a blocking region, overlapping the plurality of opening regions, of the connecting member.

The forming of the blocking region of the connecting member may include irradiating ultraviolet rays to the first portion.

The connecting member may include a photo initiator, an oligomer, and a monomer, and the blocking region of the connecting member may include a polymer.

The monomer may be photopolymerized by the ultraviolet rays to become the polymer.

The irradiating of the ultraviolet rays may be to irradiate toward the display panel by using the supporting member as a light blocking mask.

The manufacturing method of the display device may further include forming an additional supporting layer under the supporting member to overlap the second region of the display panel after attaching the supporting member.

The blocking region may be formed after forming the additional supporting layer.

The additional supporting layer may block ultraviolet rays.

Ultraviolet rays may be irradiated toward the display panel by using the supporting member and the additional supporting layer as light blocking masks.

According to the display device and the manufacturing method thereof according to embodiments, it is possible to prevent foreign particles from entering through the plurality of opening regions of the supporting member supporting the display panel.

The effects of the present embodiments are not limited to the above-described effects, and may be expanded in various ways in the range of the ideas and the areas of the present invention.

### BRIEF DESCRIPTION OF THE DRAWINGS

FIG. 1 is a schematic perspective view of a display device according to an embodiment.

FIG. 2 is a cross-sectional view of a display device according to an embodiment.

FIG. 3 is a cross-sectional view of a display device according to another embodiment.

FIG. 4 to FIG. 8 are cross-sectional views showing a manufacturing method of a display device according to an embodiment.

FIG. 9 and FIG. 10 are schematic views showing some layers of a display device according to an embodiment.

### DETAILED DESCRIPTION

The present invention will be described more fully hereinafter with reference to the accompanying drawings, in which embodiments of the invention are shown. As those skilled in the art would realize, the described embodiments may be modified in various different ways, all without departing from the spirit or scope of the present invention.

In order to clarify the present invention, parts that are not connected with the description will be omitted, and the same elements or equivalents are referred to by the same reference numerals throughout the specification.

Further, the accompanying drawings are provided only in order to allow embodiments disclosed in the present specification to be easily understood, and are not to be interpreted as limiting the spirit disclosed in the present specification, and it is to be understood that the present invention includes all modifications, equivalents, and substitutions without departing from the scope and spirit of the present invention.

Further, since sizes and thicknesses of constituent members shown in the accompanying drawings are arbitrarily given for better understanding and ease of description, the present invention is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

In addition, in the specification, when referring to “connected to”, this does not only mean that two or more constituent elements are directly connected, but also that two or more constituent elements are electrically connected through other constituent elements as well as being indirectly connected and being physically connected, or it may mean that they are referred to by different names according to a position or function, but are integrated.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, various embodiments and variations are described in detail with reference to the drawings.

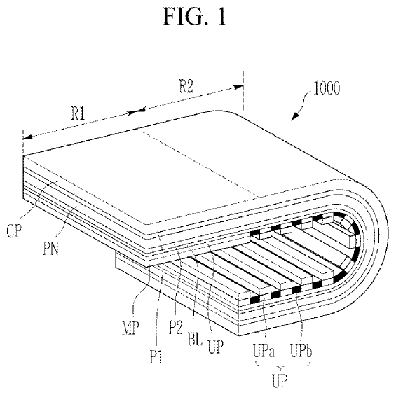

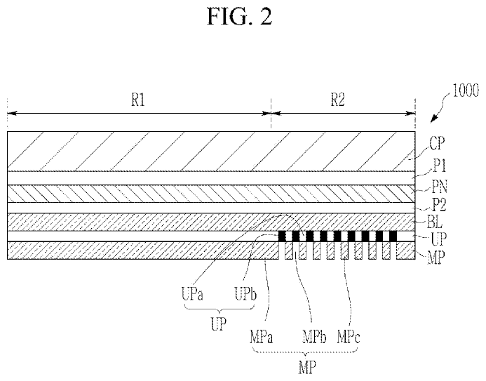

First, a display device according to an embodiment is described with reference to FIG. 1 and FIG. 2. FIG. 1 is a schematic perspective view of a display device in a folded state according to an embodiment, and FIG. 2 is a cross-sectional view of a display device in an unfolded state according to an embodiment.

Referring to FIG. 1 and FIG. 2, the display device 1000 according to an embodiment includes a display panel PN that displays an image by a plurality of pixels therein, an upper structure CP disposed above the display panel PN, and a supporting member MP disposed below the display panel PN to support the display panel PN.

The upper structure CP may include a touch sensor layer or an anti-reflection layer.

A barrier layer BL may be disposed between the display panel PN and the supporting member MP.

A first adhesive layer P1 may be disposed between the display panel PN and the upper structure CP, and a second adhesive layer P2 may be disposed between the display panel PN and the barrier layer BL.

A connecting member UP may be disposed between the barrier layer BL and the supporting member MP.

The display panel PN may include a flat first region R1 that is flat and a second region R2 that is connected to the first region R1 and may be bendable.

The second region R2 may be a rabble region or a slidable region.

A part of the supporting member MP overlapping with the first region R1 of the display panel PN may be a plate-shaped part MPa having a plate shape, and another part of the supporting member MP overlapping the second region R2 of the display panel PN may include a plurality of opening regions MPb and a non-opening region MPc between the adjacent opening regions MPb.

The supporting member MP may include a metal capable of blocking light.

By defining a plurality of opening regions MPb in the region overlapping the second region R2 of the display panel PN and among the non-opening regions MPc supporting the display panel PN, it is possible to facilitate bending of the display device 1000 in the second region R2.

The connecting member UP in contact with the supporting member MP may include an adhesive region UPa having an adhesive property and a blocking region UPb having no adhesive property or having a lower adhesive property than the adhesive region UPa.

The blocking region UPb of the connecting member UP may overlap a plurality of opening regions MPb of the supporting member MP, and the adhesive region UPa of the connecting member UP may overlap the non-opening region MPc and the plate-shaped part MPa of the supporting member MP.

The adhesive region UPa of the connecting member UP may include a photo initiator, an oligomer, and a monomer, and the blocking region UPb of the connecting member UP may include a polymer.

The blocking region UPb of the connecting member UP may have almost zero adhesive property.

As such, the supporting member MP includes a plurality of opening regions MPb formed in the region overlapping the second region R2, which is a rollable or slidable region, so that the second region R2 may be easily bent.

In addition, as the connecting member UP disposed between the supporting member MP and the display panel PN includes the blocking region UPb having no adhesive property or having a lower adhesive property than the adhesive region UPa and overlapping a plurality of opening regions MPb of the supporting member MP, external foreign particles that may be inflowed through a plurality of opening regions MPb of the supporting member MP from the outside may be prevented from being attached to the adhesive layer (specifically, the blocking region UPb) and from being visually recognized from the outside or from flowing toward the display panel PN.

The blocking region UPb of the connecting member UP may be formed by irradiating ultraviolet (“UV”) rays.

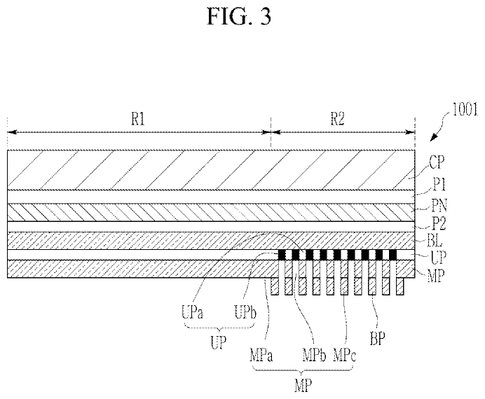

Hereinafter, a display device according to another embodiment is described with reference to FIG. 3 together with FIG. 1. FIG. 3 is a cross-sectional view of a display device according to another embodiment.

Referring to FIG. 3 together with FIG. 1, the display device 1001 according to the present embodiment is similar to the display device 1000 according to the embodiment described with reference to FIG. 1 and FIG. 2. A detailed description of the same constituent elements is omitted.

However, unlike the display device 1000 according to the embodiment described with reference to FIG. 1 and FIG. 2, the display device 1001 according to the present embodiment may further include an additional supporting layer BP disposed to overlap the non-opening region MPc of the supporting member MP, and the additional supporting layer BP may include a metal capable of blocking light.

As such, by further including the additional supporting layer BP disposed to overlap the non-opening region MPc of the supporting member MP, the adhesive region UPa between the blocking regions UPb of the connecting member UP and the non-opening region MPc of the supporting member MP may be helped to be adhered well to each other.

The supporting member MP includes a plurality of opening regions MPb defined in the region overlapping the second region R2 so that the second region R2 may be easily bent. The connecting member UP disposed between the supporting member MP and the display panel PN includes the blocking region UPb without the adhesive property or having a lower adhesive property than the adhesive region UPa to overlap a plurality of opening regions MPb of the supporting member MP so that external foreign particles that can be inflowed through a plurality of opening regions MPb of the supporting member MP from the outside may be prevent from being attached to the blocking region UPb, from being visually recognized from the outside or from flowing toward the display panel PN.

Many features of the display device 1000 according to the embodiment described above are applicable to the display device 1001 according to the present embodiment.

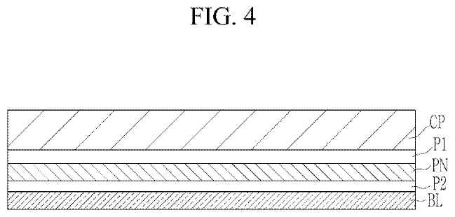

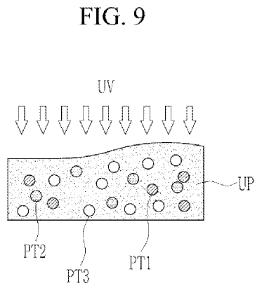

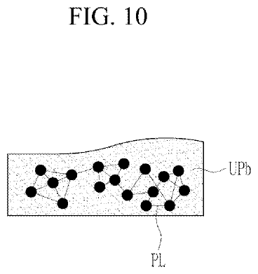

Hereinafter, a manufacturing method of the display device according to an embodiment is described with reference to FIG. 9 and FIG. 10 along with FIG. 4 to FIG. 8. FIG. 4 to FIG. 8 are cross-sectional views showing a manufacturing method of a display device according to an embodiment, and FIG. 9 and FIG. 10 are schematic views showing some layers of a display device according to an embodiment.

As shown in FIG. 4, the upper structure CP is attached on the display panel PN through the first adhesive layer P1, and the barrier layer BL is attached under the display panel PN through the second adhesive layer P2.

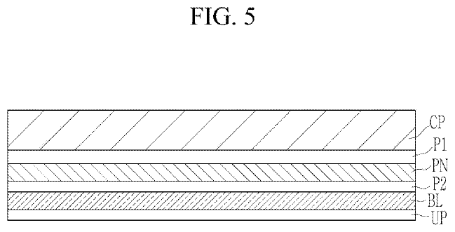

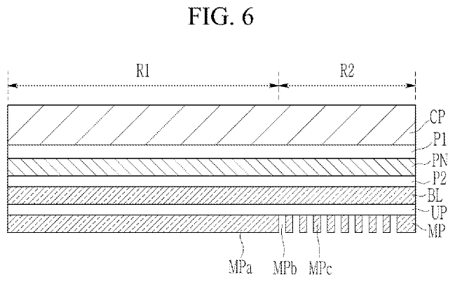

As shown in FIG. 5, the connecting member UP is attached under the barrier layer BL attached under the bottom of the display panel PN, and as shown in FIG. 6, the supporting member MP is attached under the barrier layer BL through the connecting member UP.

The display panel PN may include a first region R1 that is flat and a second region R2 connected to the first region R1 and capable of being bent, and the supporting member MP may include a plate-shaped part MPa overlapping the first region R1 of the display panel PN, a plurality of opening regions MPb overlapping the second region R2 of the display panel PN, and a non-opening region MPc between the adjacent opening regions MPb. The supporting member MP may include a metal capable of blocking light.

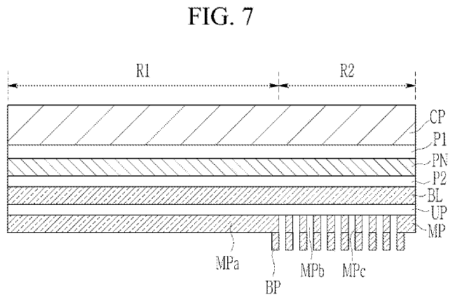

As shown in FIG. 7, the additional supporting layer BP may be attached under the supporting member MP overlapping the second region R2. The additional supporting layer BP may be disposed to overlap the non-opening region MPc, and the additional supporting layer BP may include a metal capable of blocking light. In another embodiment, the step of attaching the additional supporting layer BP under the supporting member MP overlapping the second region R2 may be omitted.

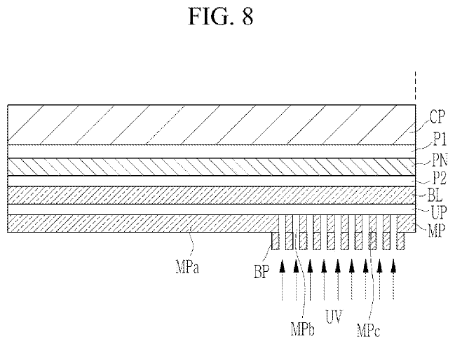

As shown in FIG. 8, by irradiating ultraviolet (UV) rays from the bottom of the supporting member MP toward the display panel PN to remove the adhesive property of the region, overlapping with a plurality of opening regions MPb of the supporting member MP, among the connecting member UP, a plurality of blocking regions UPb overlapping a plurality of opening regions MPb of the supporting member MP may be formed. At this time, the plate-shaped part MPa and the non-opening region MPc of the supporting member MP can serve as a mask that blocks ultraviolet rays when irradiating ultraviolet rays to the connecting member UP. In addition, the additional supporting layer BP may also act as a mask to block ultraviolet rays.

Referring to FIGS. 9 and 10, the connecting member UP may include a photo initiator PT1, an oligomer PT2, and a monomer PT3, and when the connecting member UP is irradiated with ultraviolet rays, the monomer PT3 of the portion irradiated with ultraviolet rays among the connecting member UP is photopolymerized to become a polymer PL, whereby the adhesive property may be reduced.

The supporting member MP includes a plurality of opening regions MPb formed in the region overlapping the second region R2, which is the rollable or slidable region, so that the second region R2 may be easily bent, and the region, overlapping a plurality of opening regions MPb of the supporting member MP, among the connecting member UP disposed between the supporting member MP and the display panel PN is formed as the blocking region UPb without the adhesive property, so that external foreign particles that can be inflowed through a plurality of opening regions MPb of the supporting member MP from the outside may be prevented from being attached to the adhesive layer UP (especially, the blocking region UPb) to prevent them from being visually recognized from the outside or from flowing toward the display panel PN.

Also, by irradiating ultraviolet rays (UV) from the bottom side of the supporting member MP toward the display panel PN and using the supporting member MP as a mask, when removing the adhesive property of the region, overlapping with a plurality of opening regions MPb of the supporting member MP, among the connecting member UP, a plurality of blocking regions UPb overlapping a plurality of opening regions MPb of the supporting member MP may be formed, thereby easily forming a plurality of blocking regions UPb without increasing a manufacturing cost.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

1000, 1001: display device
PN: display panel
CP: upper structure
MP: supporting member
MPa: plate-shaped portion
MPb: opening region
MPc: non-opening region
BL: barrier layer
BP: additional supporting layer
P1, P2, UP: adhesive layer
UPa: adhesive region
UPb: blocking region

What is claimed is:

1. A display device comprising:
a display panel including a first region and a bendable second region connected to the first region;
a supporting member supporting the display panel and defining a plurality of opening regions therein overlapping the second region; and
a connecting member disposed between the display panel and the supporting member and including a first portion overlapping the plurality of opening regions of the supporting member and a second portion overlapping a region of the supporting member except for the plurality of opening regions,
wherein the first portion of the connecting member has no adhesive property or has a lower adhesive property than the second portion.

2. The display device of claim 1, wherein
the first portion of the connecting member includes a polymer, and
the second portion of the connecting member includes a photo initiator, an oligomer, and a monomer.

3. The display device of claim 2, wherein
the first portion of the connecting member is photopolymerized by ultraviolet rays to become the polymer.

4. The display device of claim 1, wherein
the second region of the display panel is a rollable or slidable region.

5. The display device of claim 1, wherein
the supporting member blocks light.

6. The display device of claim 1, further comprising
an additional supporting layer overlapping the second region and disposed under the supporting member.

7. The display device of claim 6, wherein
the additional supporting layer overlaps a non-opening region of the supporting member disposed between the plurality of opening regions of the supporting member.

8. The display device of claim 7, wherein
the additional supporting layer does not overlap the plurality of opening regions of the supporting member.

9. The display device of claim 8, wherein
the additional supporting layer blocks light.

10. A manufacturing method of a display device, comprising:
forming a display panel including a first region and a second region that is connected to the first region and is bendable;
disposing a connecting member under the display panel;
attaching a supporting member supporting the display panel, disposed under the connecting member, and defining a plurality of opening regions therein overlapping the second region; and
removing or reducing an adhesive property of a first portion, overlapping the plurality of opening regions of the supporting member, of the connecting member to form a blocking region, overlapping the plurality of opening regions, of the connecting member.

11. The manufacturing method of the display device of claim 10, wherein
the forming of the blocking region of the connecting member includes irradiating ultraviolet rays to the first portion.

12. The manufacturing method of the display device of claim 11, wherein
the connecting member includes a photo initiator, an oligomer, and a monomer, and
the blocking region of the connecting member includes a polymer.

13. The manufacturing method of the display device of claim 12, wherein
the monomer is photopolymerized by the ultraviolet rays to become the polymer.

14. The manufacturing method of the display device of claim 11, wherein
the irradiating of the ultraviolet rays is to irradiate the ultraviolet rays toward the display panel by using the supporting member as a light blocking mask.

15. The manufacturing method of the display device of claim 10, further comprising
forming an additional supporting layer under the supporting member to overlap the second region of the display panel after attaching the supporting member.

16. The manufacturing method of the display device of claim 15, wherein
the blocking region is formed after forming the additional supporting layer.

17. The manufacturing method of the display device of claim 16, wherein
the additional supporting layer blocks ultraviolet rays.

18. The manufacturing method of the display device of claim 17, wherein
the ultraviolet rays are irradiated toward the display panel by using the supporting member and the additional supporting layer as light blocking masks.
